(19) United States
(12) Patent Application Publication
(10) Pub. No.: US 2024/0147682 A1
(43) Pub. Date: May 2, 2024

(54) APPARATUS FOR MANUFACTURING DISPLAY APPARATUS AND METHOD OF MANUFACTURING DISPLAY APPARATUS

(71) Applicant: Samsung Display Co., Ltd., Yongin-si (KR)

(72) Inventors: Taekyong Lee, Yongin-si (KR); Daeyeol Han, Yongin-si (KR)

(21) Appl. No.: 18/221,304

(22) Filed: Jul. 12, 2023

(30) Foreign Application Priority Data
Oct. 31, 2022 (KR) 10-2022-0143024

(51) Int. Cl. H05K 13/08; H05K 13/00; H05K 13/02

(52) U.S. Cl. CPC H05K 13/081; H05K 13/0015; H05K 13/0053; H05K 13/02; H05K 13/084; H05K 13/0882; H05K 13/089

(57) ABSTRACT

An apparatus for manufacturing a display apparatus includes a controller configured to control a second stage, wherein the controller includes an image processor configured to calculate position information of a first material and a second material and alignment information of a bonded material based on image information sensed by a camera unit, an operator configured to calculate final bonding position based on the position information of the first material and the second material calculated by the image processor, a controller unit configured to move the second stage to the final bonding position calculated by the operator, and a deep learning unit configured to update the operator through deep learning based on the alignment information of the bonded material calculated by the image processor.

### CROSS-REFERENCE TO RELATED APPLICATION

The present application claims priority to and the benefit of Korean Patent Application No. 10-2022-0143024, filed on Oct. 31, 2022, in the Korean Intellectual Property Office, the entire disclosure of which is incorporated herein by reference.

### BACKGROUND

### 1. Field

Aspects of one or more embodiments relate to an apparatus and a method.

### 2. Description of the Related Art

Mobile electronic apparatuses are widely used. As mobile electronic apparatuses, recently, tablet personal computers (PCs) have become widely used, as well as miniaturized electronic apparatuses such as mobile phones.

To support various functions, for example, to provide a user with visual information, such as images, mobile electronic apparatuses include a display apparatus. Recently, as the components driving a display apparatus have been miniaturized, the proportion of the display apparatus in an electronic apparatus has gradually increased and a structure that may be bent to form a preset angle with respect to a flat state is also under development.

The above information disclosed in this Background section is only for enhancement of understanding of the background and therefore the information discussed in this Background section does not necessarily constitute prior art.

### SUMMARY

Aspects of one or more embodiments relate to an apparatus and a method, and for example, to an apparatus for manufacturing a display apparatus and a method of manufacturing a display apparatus.

Aspects of one or more embodiments include bonding two materials to each other with a minimum error.

Some embodiments according to the present disclosure may be capable of reducing an alignment error between two materials as a bonding process is repeated through feedback using deep learning technology in a bonding process of bonding two materials to each other.

However, such a technical characteristic is an example, and embodiments according to the present disclosure are not limited thereto.

Additional aspects will be set forth in part in the description which follows and, in part, will be apparent from the description, or may be learned by practice of the presented embodiments of the disclosure.

According to one or more embodiments, an apparatus for manufacturing a display apparatus includes a first stage supporting a first material, a second stage supporting a second material and moving to a final bonding position to bond the first material and the second material into a bonded material, a camera unit configured to sense image information of the first material, the second material, and the bonded material, and a controller configured to control the second stage, wherein the controller includes an image processor configured to calculate position information of the first material and the second material and alignment information of the bonded material based on the image information sensed by the camera unit, an operator configured to calculate the final bonding position based on the position information of the first material and the second material calculated by the image processor, a controller unit configured to move the second stage to the final bonding position calculated by the operator, and a deep learning unit configured to update the operator through deep learning based on the alignment information of the bonded material calculated by the image processor.

According to some embodiments, the operator may include an initial bonding position calculator configured to calculate an initial bonding position based on the position information of the first material and the second material calculated by the image processor, and a bonding position corrector configured to correct the initial bonding position to the final bonding position according to a first correction model.

According to some embodiments, the deep learning unit may include an error calculator configured to calculate an alignment error of the bonded material based on the alignment information of the bonded material calculated by the image processor, a correction model corrector configured to correcting the first correction model to a second correction model based on the alignment error calculated by the error calculator, and a correction model updater configured to update the bonding position corrector to correct the initial bonding position to the final bonding position according to the second correction model.

According to some embodiments, the second correction model may be based on calibration information between the first stage and the second stage, and the camera unit, the position information of the first material and the second material calculated by the image processor, the initial bonding position calculated by the initial bonding position calculator, and the first correction model.

According to some embodiments, the bonding position corrector may be configured to correct the initial bonding position to the final bonding position according to the second correction model, the correction model corrector may be configured to correct the second correction model to a third correction model based on the alignment error calculated by the error calculator, and the correction model updater may be configured to update the bonding position corrector to correct the initial bonding position to the final bonding position according to the third correction model.

According to some embodiments, the correction model corrector may be configured to correct the second correction model to the third correction model by taking into account calibration information between the first stage and the second stage, and the camera unit, the position information of the first material and the second material calculated by the image processor, the initial bonding position calculated by the initial bonding position calculator, the first correction model, and the second correction model.

According to some embodiments, the apparatus may further include a first chamber in which the first stage and the second stage are located, wherein the camera unit may include a first camera inside the first chamber and configured to sense image information of the first material, and a second camera inside the first chamber and configured to sense image information of the second material.

According to some embodiments, at least one of the first camera or the second camera may be configured to sense image information of the bonded material.

According to some embodiments, the apparatus may further include a third stage supporting the bonded material, a second chamber in which the third stage is located, and a carrier robot configured to carry the bonded material inside the first chamber to an inside of the second chamber, wherein the camera unit may further include a third camera inside the second chamber and configured to sense image information of the bonded material carried to the inside of the second chamber.

According to some embodiments, the first material may include one of a substrate and a cover window, and the second material may include the other of the substrate and the cover window.

According to one or more embodiments, in a method of manufacturing a display apparatus, the method includes arranging a first material on a first stage, arranging a second material on a second stage, sensing, by a camera unit, image information of the first material and the second material, calculating position information of the first material and the second material based on the image information of the first material and the second material, calculating, by an operator, a final bonding position of the second stage such that the first material and the second material are bonded into a bonded material based on the position information of the first material and the second material, moving the second stage to the final bonding position, sensing, by the camera unit, image information of the bonded material, calculating alignment information of the bonded material based on the image information of the bonded material, and updating the operator through deep learning based on the alignment information of the bonded material.

According to some embodiments, the method may further include calculating an initial bonding position based on the position information of the first material and the second material, and correcting the initial bonding position to the final bonding position according to a first correction model.

According to some embodiments, the method may further include calculating an alignment error of the bonded material based on the alignment information of the bonded material, correcting the first correction model to a second correction model based on the alignment error of the bonded material, and correcting the initial bonding position to the final bonding position according to the second correction model.

According to some embodiments, the second correction model may be based on calibration information between the first stage and the second stage, and the camera unit, the position information of the first material and the second material, the initial bonding position, and the first correction model.

According to some embodiments, the method may further include correcting the initial bonding position to the final bonding position according to the second correction model, correcting the second correction model to a third correction model based on the alignment error of the bonded material, and correcting the initial bonding position to the final bonding position according to the third correction model.

According to some embodiments, the method may further include correcting the second correction model to the third correction model by taking into account calibration information between the first stage and the second stage, and the camera unit, the position information of the first material and the second material, the initial bonding position, the first correction model, and the second correction model.

According to some embodiments, the method may further include arranging the first stage and the second stage inside a first chamber, arranging a first camera inside the first chamber, wherein the first camera is configured to sense image information of the first material, and arranging a second camera inside the first chamber, wherein the second camera is configured to sense image information of the second material.

According to some embodiments, the method may further include sensing image information of the bonded material by at least one of the first camera or the second camera.

According to some embodiments, the method may further include arranging a third stage inside a second chamber, arranging a third camera inside the second chamber, carrying the bonded material from the first chamber to the second chamber such that the bonded material is on the third stage, and sensing, by the third camera, image information of the bonded material.

According to some embodiments, the first material may include one of a substrate and a cover window, and the second material may include the other of the substrate and the cover window.

These and/or other aspects will become apparent and more readily appreciated from the following detailed description of the embodiments, the accompanying drawings, and claims and their equivalents.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic cross-sectional view of an apparatus for manufacturing a display apparatus according to some embodiments;

FIG. 2 is a schematic perspective view of a first camera according to some embodiments;

FIG. 3 is a schematic cross-sectional view of an apparatus for manufacturing a display apparatus according to some embodiments;

FIG. 4 is a schematic cross-sectional view of an apparatus for manufacturing a display apparatus according to some embodiments;

FIG. 5 is a schematic perspective view of a third camera according to some embodiments, and FIG. 6 is a schematic plan view of a bonded material according to some embodiments;

FIG. 7 is a schematic view of a controller according to some embodiments;

FIG. 8 is a flowchart showing a method of manufacturing a display apparatus according to some embodiments;

FIG. 9 is a schematic plan view of a display apparatus according to some embodiments;

FIG. 10 is a schematic cross-sectional view of a display apparatus according to some embodiments;

FIG. 11 is an equivalent circuit diagram of one of pixels in a display panel according to some embodiments;

FIG. 12 is a schematic cross-sectional view of an apparatus for manufacturing a display apparatus according to some embodiments;

FIG. 13 is a schematic cross-sectional view of an apparatus for manufacturing a display apparatus according to some embodiments;

FIG. 14 is a schematic cross-sectional view of an apparatus for manufacturing a display apparatus according to some embodiments; and

FIG. 15 is a schematic cross-sectional view of an apparatus for manufacturing a display apparatus according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to aspects of some embodiments described below in more detail with reference to the drawings. However, embodiments according to the present disclosure are not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The X-axis, the Y-axis and the Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

In the case where a certain embodiment may be implemented differently, a specific process order may be performed in the order different from the described order. As an example, two processes successively described may be simultaneously performed substantially and performed in the opposite order.

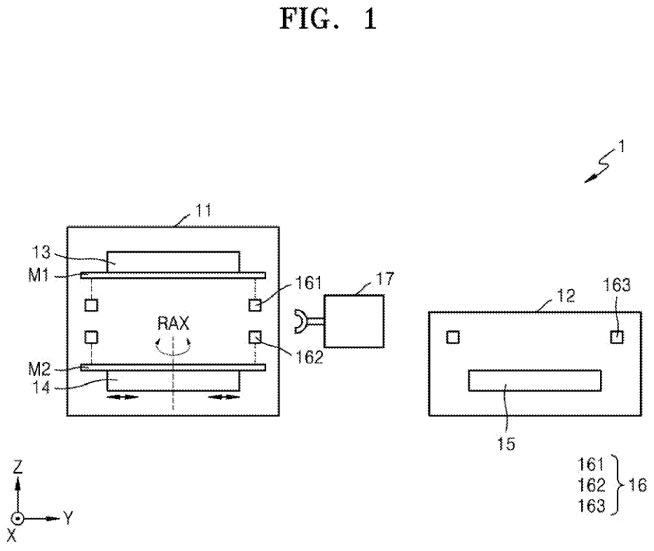

FIG. 1 is a schematic cross-sectional view of an apparatus 1 for manufacturing a display apparatus according to some embodiments.

Referring to FIG. 1, the apparatus 1 for manufacturing a display apparatus may include a first chamber 11, a second chamber 12, a first stage 13, a second stage 14, a third stage 15, a camera unit 16, a carrier robot 17, a controller, and a communication unit. The carrier robot 17, the controller, and the communication unit are described in more detail below.

The first chamber 11 may have an inner space.

The first stage 13 may be located inside the first chamber 11 and may support a first material M1. The first stage 13 may support one surface (e.g., a surface facing a +Z axis) of the first material M1 on the upper portion of the first material M1. The first stage 13 may be fixedly arranged with respect to the first chamber 11.

The second stage 14 may be located inside the first chamber 11 and may support a second material M2. The second stage 14 may support one surface (e.g., a surface facing a −Z axis) of the second material M2 on the lower portion of the second material M2. The second stage 14 may be movable with respect to the first chamber 11. The second stage 14 may be configured to align the second material M2 such that the second material M2 supported b″ the′ second stage 14 is bonded to the first material M1 supported by the first stage 13 at an exact position. As an example, the second stage 14 may perform a linear motion with respect to the first stage 13 and perform a rotational motion around a rotational axis RAX.

The camera unit 16 may be configured to sense image information of the first material M1 and the second material M2. The camera unit 16 may include a first camera 161, a second camera 162, and a third camera 163. The first camera 161 and the second camera 162 may be located inside the first chamber 11, and the third camera 163 may be located inside the second chamber 12. The first camera 161 may be configured to sense image information of the first material M1, and the second camera 162 may be configured to sense image information of the second material M2.

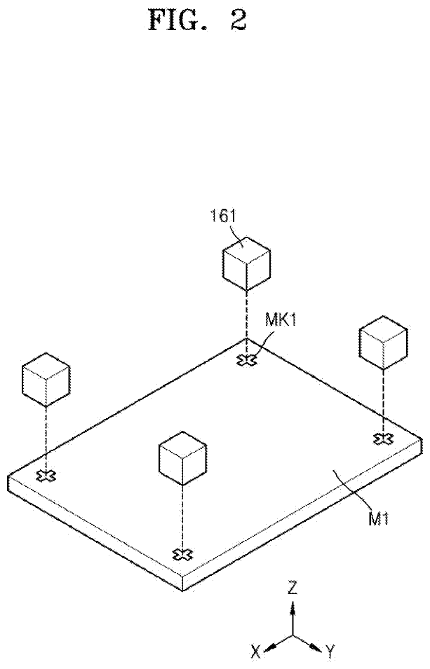

FIG. 2 is a schematic perspective view of the first camera 161 according to some embodiments.

Referring to FIG. 2, the first camera 161 may be configured to sense image information of the first material M1.

A plurality of first marking portions MK1 may be located on the first material M1. The plurality of first marking portions MK1 may be arranged in a region adjacent to the edges of the first material M1. The first camera 161 may be configured to recognize the position of each of the first marking portions MK1.

As an example, the shape of the first material M1 may be a quadrangular plate shape. Four first marking portions MK1 may be respectively arranged to be adjacent to four vertexes of the first material M1. The number of first cameras 161 corresponding to the number of first marking portions MK1 may be provided. Four first cameras 161 may be provided. The four first cameras 161 may be configured to respectively recognize the four marking portions MK1. This is only one example, and the shape of the first material M1, the number of first marking portions MK1, and the number of first cameras 161 are not limited thereto. In addition, though each of the plurality of first marking portions MK1 is shown to have a ‘+’ shape in FIG. 2, this is only an example for convenience of description, and the shapes of the plurality of first marking portions MK1 are not limited thereto.

Because the method of sensing, by the first camera 161, image information of the first material M1 is described with reference to FIG. 2 and a method of sensing, by the second camera 162, image information of the second material M2 is the same, detailed description thereof is omitted.

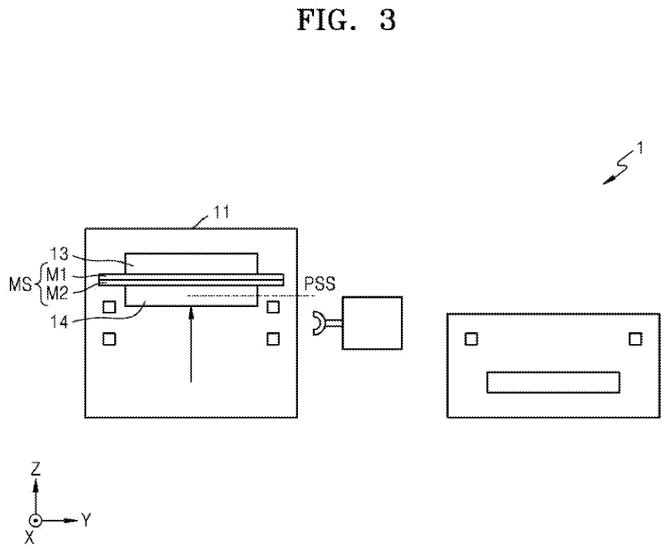

FIG. 3 is a schematic cross-sectional view of the apparatus 1 for manufacturing a display apparatus according to some embodiments.

Referring to FIG. 3, after the process described with reference to FIG. 1, the second stage 14 may move to a final bonding position PSS such that the first material M1 and the second material M2 are bonded into a bonded material MS. The second stage 14 may linearly move in a second direction (e.g., a +Z axis direction) toward the first stage 13. As an example, the second stage 14 located below the first stage 13 may move upward toward the first stage 13. As the second stage 14 moves to the final bonding position PSS, the first material M1 and the second material M2 may contact each other and be bonded into the bonded material MS.

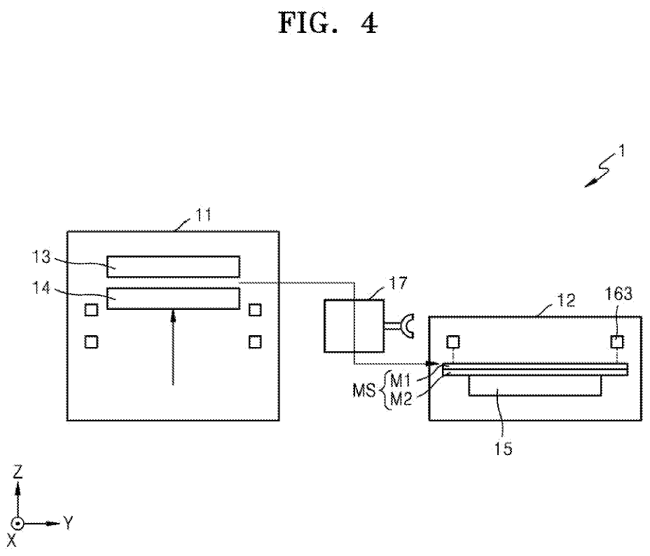

FIG. 4 is a schematic cross-sectional view of the apparatus 1 for manufacturing a display apparatus according to some embodiments.

Referring to FIG. 4, after the process described with reference to FIG. 3, the carrier robot 17 may be configured to carry the bonded material MS located inside the first chamber 11 to the inside of the second chamber 12.

The second chamber 12 may provide an inner space.

The third stage 15 may be located inside the second chamber 12 and may support the bonded material MS. That is, the carrier robot 17 may be configured to carry the bonded material MS from the inside of the first chamber 11 to the inside of the second chamber 12 such that the bonded material MS is located on the third stage 15. The third stage 15 may support one surface (e.g., a surface facing a +Z axis) of the bonded material MS. The third stage 15 may be fixedly arranged with respect to the second chamber 12.

The third camera 163 may be located inside the second chamber 12. The third camera 163 may be configured to sense image information of the bonded material MS.

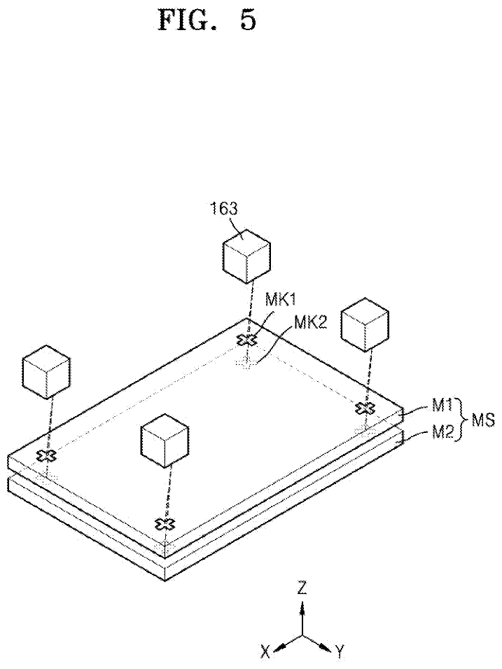

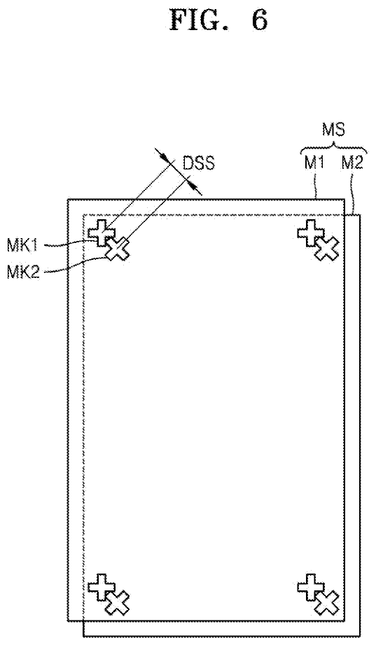

FIG. 5 is a schematic perspective view of the third camera 163 according to some embodiments, and FIG. 6 is a schematic plan view of the bonded material MS according to some embodiments.

Referring to FIGS. 5 and 6, the third camera 163 may be configured to sense image information of the bonded material MS.

The third camera 163 may be configured to recognize each of the plurality of first marking portions MK1 located on the first material M1 and the plurality of second marking portion MK2 located on the second material M2. The third camera 163 may be configured to sense each of distances DSS between the plurality of first marking portions MK1 and the plurality of second marking portions MK2 adjacent to the plurality of first marking portions MK1. As an example, as shown in FIG. 5, each of the plurality of first marking portions MK1 may have a ‘+’ shape, and each of the plurality of second marking portions MK2 may have an ‘X’ shape. In this case, the third camera 163 may be configured to recognize each of distances DSS between the center of the ‘+’ shape of the first marking portions MK1 and the center of the ‘X’ shape of the second marking portions MK2.

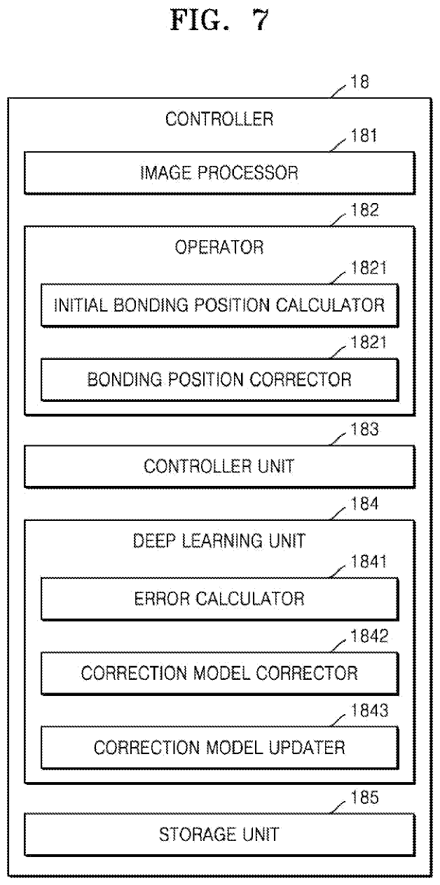

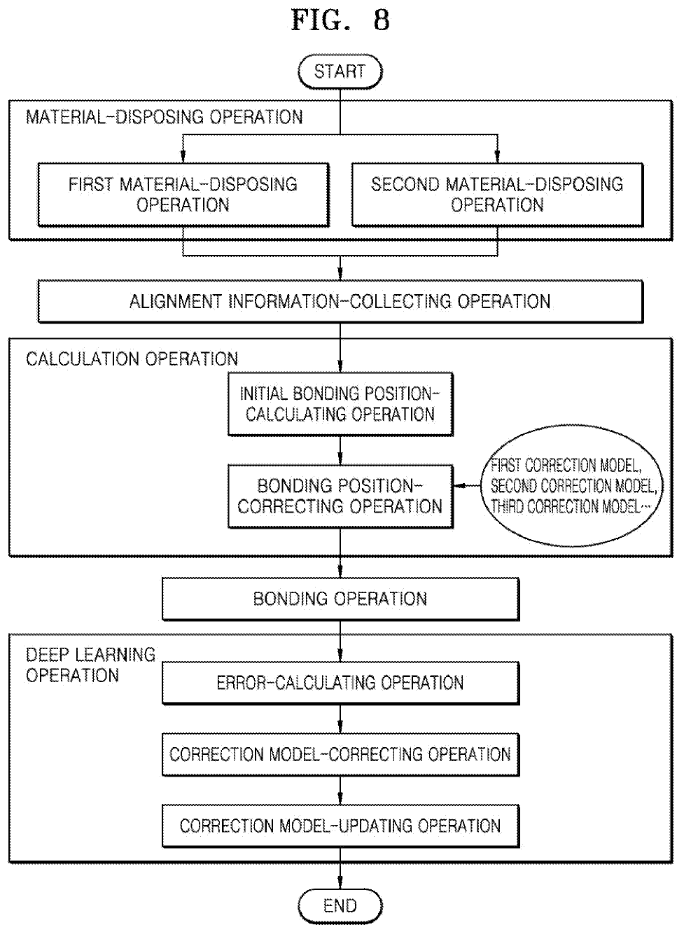

FIG. 7 is a schematic view of a configuration of a controller 18 according to some embodiments, and FIG. 8 is a flowchart showing a method of manufacturing a display apparatus according to some embodiments.

Referring to FIGS. 7 and 8, the controller 18 may be configured to control the second stage 14 (see FIG. 1). The controller 18 may include an image processor 181, an operator 182, a controller unit 183, a deep learning unit 184, and a storage unit 185.

In the process described with reference to FIG. 1, the first material M1 is located on the first stage 13, the second material M2 is located on the second stage 14, and the camera unit 16 may be configured to sense image information of the first material M1 and the second material M2. That is, the camera unit 16 may be configured to collect alignment information of the first material M1 and the second material M2.

In this case, the image processor 181 may be configured to calculate position information of the first material M1 and the second material M2 based on the image information of the first material M1 and the second material M2 sensed by the camera unit 16. The image processor 181 may be configured to calculate a relative position relationship between the first material M1 and the second material M2 based on the position of the first marking portion MK1 (see FIG. 2) of the first material M1 recognized by the first camera 161 and the position of the second marking portion MK2 of the second material M2 recognized by the second camera 162. As an example, the image processor 181 may be configured to calculate a degree by which the first material M1 is apart from the second material M2 in a first direction (an X axis direction and/or an Y axis direction), and a degree by which the first material M1 and the second material M2 are distorted around the rotational axis RAX of the second stage 14.

The operator 182 may be configured to calculate the final bonding position PSS based on the position information of the first material M1 and the second material M2 calculated by the image processor 181. The operator 182 may include an initial bonding position calculator 1821 and a bonding position corrector 1822.

The initial bonding position calculator 1821 may be configured to calculate the initial bonding position based on the position information of the first material M1 and the second material M2 calculated by the image processor 181. As an example, in the case where the second material M2 is apart from the first material M1 by a first distance in a (1-1)st direction (e.g., the +Y axis direction) and distorted around the rotational axis RAX of the second stage 14 by a first angle, the initial bonding position calculator 1821 may be configured to calculate the final bonding position PSS such that the second material M2 moves with respect to the first material M1 in a (1-2)nd direction (e.g., a −Y axis direction) opposite to the (1-1)st direction and rotates around the rotational axis RAX of the second stage 14 by a second angle opposite to the first angle.

The bonding position corrector 1822 may be configured to correct the initial bonding position to the final bonding position PSS according to a first correction model. The bonding position corrector 1822 may be configured to correct the initial bonding position to the final bonding position by reflecting information unexpected by the initial bonding position calculator 1821 in an operation of calculating the initial bonding position. In a state not learned through the deep learning unit 184, an output of the first correction model may be 0. That is, in a state not learned through the deep learning unit 184, the bonding position corrector 1822 does not correct the initial bonding position, and the final bonding position PSS may be the same as the initial bonding position.

In the process described with reference to FIG. 3, the controller unit 183 may be configured to move the second stage 14 to the final bonding position PSS calculated by the operator 182.

In the process described with reference to FIG. 4, the bonded material MS is located on the third stage 15, and the camera unit 16 may be configured to sense image information of the bonded material MS.

In this case, the image processor 181 may be configured to calculate alignment information of the bonded material MS based on the image information of the bonded material MS sensed by the camera unit 16. The image processor 181 may be configured to calculate a relative position relationship between the first material M1 and the second material M2 in the bonded material MS based on each of distances between the plurality of first marking portions MK1 and the plurality of second marking portions MK2 adjacent to the plurality of first marking portions MK1, wherein the distances are recognized by the third camera 163.

The deep learning unit 184 may be configured to update the operator 182 through the deep learning based on the alignment information of the bonded material MS calculated by the image processor 181. The deep learning unit 184 may include an error calculator 1841, a correction model corrector 1842, and a correction model updater 1843. As an example, the deep learning unit 184 may use, for example, a feed-forward neural networks (FFNN) model.

The error calculator 1841 may be configured to calculate an alignment error of the bonded material MS based on alignment information of the bonded material MS calculated by the image processor 181. As an example, the image processor 181 may be configured to calculate a degree by which the first material M1 is apart from the second material M2 in a first direction (e.g., an X axis direction and/or an Y axis direction), and a degree by which the first material M1 and the second material M2 are distorted around the rotational axis RAX of the second stage 14.

The correction model corrector 1842 may be configured to correct the first correction model to a second correction model based on the alignment error calculated by the error calculator 1841. The second correction model may be based on variables unexpected by the initial bonding position calculator 1821.

The second correction model may be based on calibration information between the first stage 13 and the second stage 14, and the camera unit 16. As an example, the second correction model may be based on calibration information between the first stage 13 and the first camera 161 and calibration information between the second stage 14 and the second camera 162. In addition, the second correction model may be based on position information of the first material M1 and the second material M2 calculated by the image processor 181, the initial bonding position calculated by the initial bonding position calculator 1821, and the first correction model.

The correction model updater 1843 may be configured to update the bonding position corrector 1822 to correct the initial bonding position to the final bonding position PSS according to the second correction model.

When this process ends, the bonded material MS is taken out and the process described with reference to FIG. 1 may be repeated.

Again, in the process described with reference to FIG. 1, a new first material M1 is located on the first stage 13, a new second material M2 is located on the second stage 14, and the camera unit 16 may be configured to sense image information of the first material M1 and the second material M2.

In this case, the image processor 181 may be configured to calculate position information of the first material M1 and the second material M2 based on the image information of the first material M1 and the second material M2 sensed by the camera unit 16. In addition, the operator 182 may be configured to calculate the final bonding position PSS based on the position information of the first material M1 and the second material M2 calculated by the image processor 181.

The initial bonding position calculator 1821 may be configured to calculate the initial bonding position based on the position information of the first material M1 and the second material M2 calculated by the image processor 181.

The bonding position corrector 1822 may be configured to correct the initial bonding position to the final bonding position PSS according to the second correction model.

In the process described with reference to FIG. 3, the controller unit 183 may be configured to move the second stage 14 to the final bonding position PSS calculated by the operator 182.

In the process described with reference to FIG. 4, the bonded material MS is located on the third stage 15, and the camera unit 16 may be configured to sense image information of the bonded material MS.

In this case, the image processor 181 may be configured to calculate alignment information of the bonded material MS based on the image information of the bonded material MS sensed by the camera unit 16. In addition, the deep learning unit 184 may be configured to update the operator 182 through the deep learning based on the alignment information of the bonded material MS calculated by the image processor 181.

The error calculator 1841 may be configured to calculate an alignment error of the bonded material MS based on alignment information of the bonded material MS calculated by the image processor 181. The correction model corrector 1842 may be configured to correct the second correction model to a third correction model based on the alignment error calculated by the error calculator 1841.

In this case, like the second correction model, the third correction model may be based on the calibration information between the first stage 13 and the second stage 14, and the camera unit 16. As an example, the third correction model may be based on calibration information between the first stage 13 and the first camera 161 and calibration information between the second stage 14 and the second camera 162. In addition, the third correction model may be based on position information of the first material M1 and the second material M2 calculated by the image processor 181, the initial bonding position calculated by the initial bonding position calculator 1821, and the second correction model.

The correction model corrector 1842 may be configured to correct the second correction model to the third correction model by taking into account calibration information between the first stage 13 and the second stage 14, and the camera unit 16. As an example, the correction model corrector 1842 may be configured to correct the second correction model to the third correction model by taking into account calibration information between the first stage 13 and the first camera 161 and calibration information between the second stage 14 and the second camera 162. In addition, the correction model corrector 1842 may be configured to correct the second correction model to the third correction model by taking into account position information of the first material M1 and the second material M2 calculated by the image processor 181, the initial bonding position calculated by the initial bonding position calculator 1821, the first correction model, and the second correction model.

The correction model updater 1843 may be configured to update the bonding position corrector 1822 to correct the initial bonding position to the final bonding position PSS according to the third correction model.

When this process ends, the bonded material MS may be taken out. The process described with reference to FIGS. 1 to 8 may be repeated, and for convenience of description, some repeated description thereof may be omitted.

The storage unit 185 may be configured to store data which the controller 18 requires during a process of controlling the second stage 14. As an example, the storage unit 185 may be configured to store calibration information between the first stage 13 and the second stage 14, and the camera unit 16, the position information of the first material M1 and the second material M2 calculated by the image processor 181, the initial bonding position calculated by the initial bonding position calculator 1821, and data for the first correction model, the second correction model, and the third correction model. However, this is an example, and the data stored by the storage unit 185 is not limited thereto.

The communication unit may be connected to at least one of the first chamber 11, the second chamber 12, the first stage 13, the second stage 14, the third stage 15, the camera unit 16, the carrier robot 17, or the controller 18. The apparatus 1 for manufacturing the display apparatus may include a separate server, and the communication unit may be configured to communicate with the controller 18 through the separate server. As an example, the deep learning unit 184 is stored in the separate server, and the communication unit may be configured to communicate with the deep learning unit 184 through the separate server.

The communication unit may be configured to communicate electronically with other components using at least one of various wireless networks and wired networks, such as wireless LAN (Wi-Fi), single-hop, multi-hop, radio frequency identification (RFID), or Bluetooth. The communication unit may include a wireless relay configured to relay wireless communication. The wireless relay may form a wireless communication network and be configured using various wireless communication technologies, such as a wireless LAN, single-hop, multi-hop, and Bluetooth.

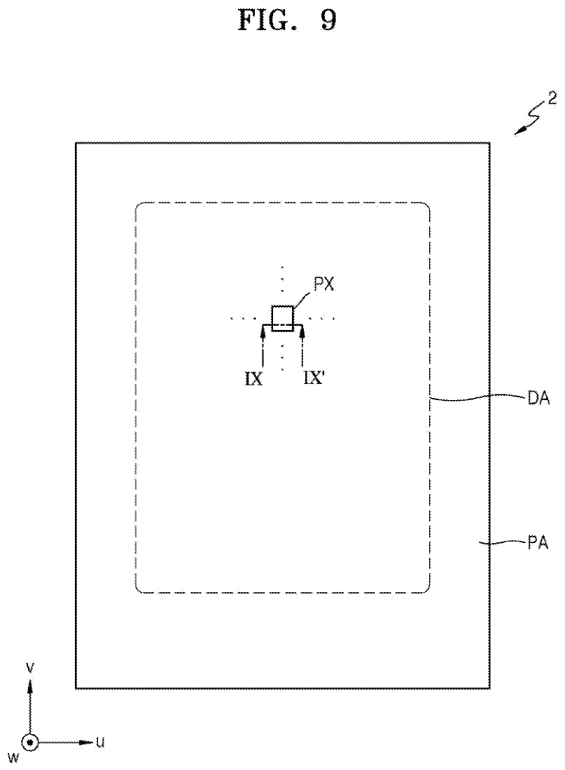

FIG. 9 is a schematic plan view of a display apparatus 2 according to some embodiments.

Referring to FIG. 9, the display apparatus 2 manufactured according to some embodiments, may include the display area DA and the peripheral area PA outside the display area DA. The display apparatus 2 may be configured to display images through an array of a plurality of pixels PX arranged two-dimensionally in the display area DA.

The peripheral area PA is a region that does not display images and may surround the display area DA entirely or partially. A driver and the like configured to provide electric signals or power to pixel circuits respectively corresponding to the pixels PX may be arranged in the peripheral area PA. A pad may be arranged in the peripheral area PA, wherein the pad is a region to which electronic elements or a printed circuit board may be electrically connected.

Hereinafter, though the display apparatus 2 includes an organic light-emitting diode OLED as a light-emitting diode, the display apparatus 2 according to some embodiments are not limited thereto. According to some embodiments, the display apparatus 2 may be a light-emitting display apparatus including an inorganic light-emitting diode, that is, an inorganic light-emitting display apparatus. The inorganic light-emitting diode may include a PN diode including inorganic material semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width in the range of several micrometers to hundreds of micrometers. According to some embodiments, the inorganic light-emitting diode may be denoted by a micro light-emitting diode. According to some embodiments, the display apparatus 2 may be a quantum-dot light-emitting display apparatus.

The display apparatus 2 may be used as a display screen in various electronic devices or products including televisions, notebook computers, monitors, advertisement boards, Internet of things (IoTs) apparatuses as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus 2 according to some embodiments may be used in wearable devices including smartwatches, watchphones, glasses-type displays, and head-mounted displays (HMD). In addition, according to some embodiments, the display apparatus 2 may be used as a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

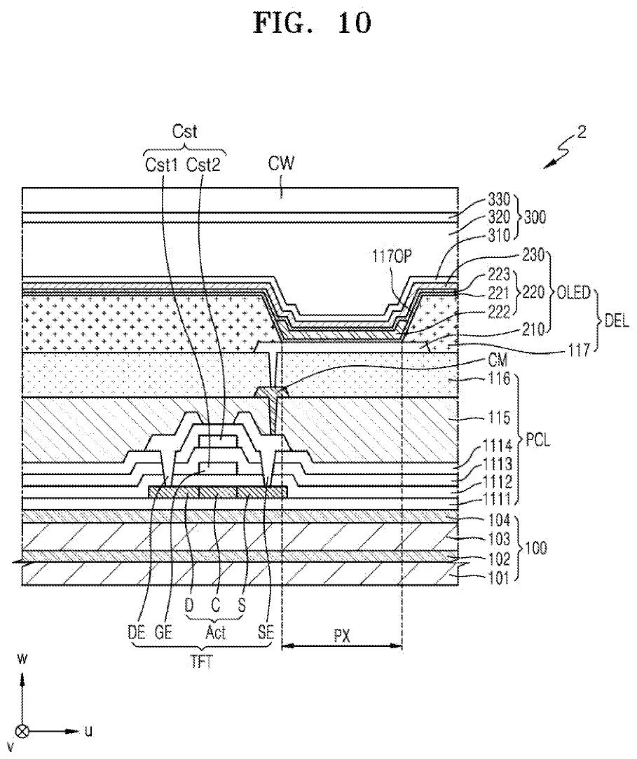

FIG. 10 is a schematic cross-sectional view of the display apparatus 2 according to some embodiments, taken along the line IX-IX′ of FIG. 9.

Referring to FIG. 10, the display apparatus 2 may include a stack structure of a substrate 100, a pixel circuit layer PCL, a display element layer DEL, and an encapsulation layer 300.

The substrate 100 may have a multi-layered structure including a base layer that includes the polymer resin and an inorganic layer. As an example, the substrate 100 may include the base layer including a polymer resin and a barrier layer including an inorganic insulating layer. As an example, the substrate 100 may include a first base layer 101, a first barrier layer 102, a second base layer 103, and a second barrier layer 104 that are sequentially stacked. The first base layer 101 and the second base layer 103 may each include polyimide (PI), polyethersulfone (PES), polyacrylate, polyetherimide (PEI), polyethylene naphthalate (PEN), polyethylene terephthalate (PET), polyphenylene sulfide (PPS), polycarbonate, cellulose tri acetate (TAC), and/or cellulose acetate propionate (CAP). The first barrier layer 102 and the second barrier layer 104 may each include an inorganic insulating material such as silicon oxide, silicon oxynitride, and/or silicon nitride. The substrate 100 may be flexible.

The pixel circuit layer PCL is located on the substrate 10. It is shown in FIG. 10 that the pixel circuit layer PCL includes a thin-film transistor TFT, a buffer layer 111, a first gate insulating layer 112, a second gate insulating layer 113, an interlayer insulating layer 114, and a first planarization insulating layer 115, and a second planarization insulating layer 116 under and/or on elements of the thin-film transistor TFT.

The buffer layer 111 may reduce or block penetration of foreign materials, moisture, or external air from below the substrate 100 and provide a flat surface on the substrate 100. The buffer layer 111 may include an inorganic insulating material such as silicon nitride, silicon oxynitride, and silicon oxide, and include a single-layered structure or a multi-layered structure including the above materials.

The thin-film transistor TFT on the buffer layer 111 may include a semiconductor layer Act, and the semiconductor layer Act may include polycrystalline silicon (poly-Si). Alternatively, the semiconductor layer Act may include amorphous silicon (a-Si), an oxide semiconductor, or an organic semiconductor. The semiconductor layer Act may include a channel region C, a drain region D, and a source region S respectively arranged on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The first gate insulating layer 112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

An upper electrode Cst2 of the storage capacitor Cst may be arranged on the second gate insulating layer 113. The upper electrode Cst2 may overlap the gate electrode GE therebelow. In this case, the gate electrode GE and the upper electrode Cst2 overlapping each other with the second gate insulating layer 113 therebetween, may constitute the storage capacitor Cst. That is, the gate electrode GE may serve as a lower electrode Cst1 of the storage capacitor Cst.

As described above, the storage capacitor Cst may overlap the thin-film transistor TFT. According to some embodiments, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂). The interlayer insulating layer 114 may include a single layer or a multi-layer including the inorganic insulating material.

The drain electrode DE and the source electrode SE may each be located on the interlayer insulating layer 114. The drain electrode DE and the source electrode SE may be respectively connected to the drain region D and the source region S through contact holes of insulating layers therebelow. The drain electrode DE and the source electrode SE may each include a material having high conductivity. The drain electrode DE and the source electrode SE may each include a conductive material including molybdenum (Mo), aluminum (Al), copper (Cu), and titanium (Ti) and include a single layer or a multi-layer including the above materials. According to some embodiments, the drain electrode DE and the source electrode SE may each have a multi-layered structure of Ti/Al/Ti.

The first planarization insulating layer 115 may cover the drain electrode DE and the source electrode SE. The first planarization insulating layer 115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The second planarization insulating layer 116 may be located on the first planarization insulating layer 115. The second planarization insulating layer 116 may include the same material as a material of the first planarization insulating layer 115 and may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be located on the pixel circuit layer PCL having the above structure. The display element layer DEL may include an organic light-emitting diode OLED as a display element (that is, a light-emitting element). The organic light-emitting diode OLED may have a stack structure of a pixel electrode 210, an intermediate layer 220, and a common electrode 230. The organic light-emitting diode OLED may be configured to emit, for example, red, green, or blue light, or emit red, green, blue, or white light. The organic light-emitting diode OLED may be configured to emit light through an emission area. The emission area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115, and a contact metal CM located on the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. According to some embodiments, the pixel electrode 210 may further include a layer on/under the reflective layer, the layer including ITO, IZO, ZnO, or In₂O₃.

A bank layer 117 may be located on the pixel electrode 210, the pixel-defining layer 117 including an opening 1170P exposing a central portion of the pixel electrode 210. The bank layer 117 may include an organic insulating material and/or an inorganic insulating material. The opening 1170P may define the emission area of light emitted from the organic light-emitting diode OLED. As an example, the size/width of the opening 1170P may correspond to the size/width of the emission area. Accordingly, the size and/or width of the pixel PX may depend on the size and/or width of the opening 1170P of the bank layer 117.

The intermediate layer 220 may include an emission layer 222 formed to correspond to the pixel electrode 210. The emission layer 222 may include a polymer organic material or a low-molecular weight organic material emitting light having a preset color. Alternatively, the emission layer 222 may include an inorganic emission material or quantum dots.

According to some embodiments, the intermediate layer 220 may include a first functional layer 221 and a second functional layer 223 respectively located under and on the emission layer 222. The first functional layer 221 may include, for example, a hole transport layer (HTL), or include an HTL and a hole injection layer (HIL). The second functional layer 223 is an element located on the emission layer 222 and may include an electron transport layer (ETL) and/or an electron injection layer (EIL). Like the common electrode 230 described below, the first functional layer 221 and/or the second functional layer 223 may be common layers covering the substrate 100 entirely.

The common electrode 230 may be located on the pixel electrode 210 and may overlap the pixel electrode 210. The common electrode 230 may include a conductive material having a low work function. As an example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the common electrode 230 may further include a layer on the (semi) transparent layer, the layer including ITO, IZO, ZnO, or In₂O₃. The common electrode 230 may be formed as one body to cover the substrate 100 entirely.

The encapsulation layer 300 may be located on the display element layer DEL and may cover the display element layer DEL. The encapsulation layer 300 may include at least one inorganic encapsulation layer and at least one organic encapsulation layer. According to some embodiments, it is shown in FIG. 10 that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, and polyethylene. According to some embodiments, the organic encapsulation layer 320 may include acrylate. The organic encapsulation layer 320 may be formed by hardening a monomer or coating a polymer. The organic encapsulation layer 320 may be transparent.

According to some embodiments, a touch sensor layer may be located on the encapsulation layer 300. An optical functional layer may be located on the touch sensor layer. The touch sensor layer may obtain coordinate information corresponding to an external input, for example, a touch event. The optical functional layer may reduce the reflectivity of light (external light) incident toward the display apparatus from outside, and/or relatively improve the color purity of light emitted from the display apparatus. According to some embodiments, the optical functional layer may include a retarder and/or a polarizer. The retarder may include a film-type retarder or a liquid crystal-type retarder. The retarder may include a λ/2 retarder and/or a λ/4 retarder. The polarizer may include a film-type polarizer or a liquid crystal-type polarizer. The film-type polarizer may include a stretchable synthetic resin film, and the liquid crystal-type polarizer may include liquid crystals arranged in an arrangement (e.g., a set or predetermined arrangement). Each of the retarder and the polarizer may further include a protective film.

An adhesive member may be located between the touch sensor layer and the optical functional layer. For the adhesive member, a general adhesive member known in the art may be employed without limitation. The adhesive member may be a pressure sensitive adhesive (PSA).

A cover window CW may be arranged over the substrate 100. The cover window CW may be located on the optical functional layer, and an adhesive member may be located between the optical functional layer and the cover window CW.

The cover window CW may be a flexible window. The cover window CW may include glass, sapphire, or plastic. The cover window CW may be, for example, ultra-thin glass (UTG) or colorless polyimide (CPI). According to some embodiments, the cover window CW may have a structure in which a flexible polymer layer is located on one surface of a glass substrate, or include only a polymer layer.

The first material M1 described with reference to FIGS. 1 to 8 may include one of the substrate 100 and the cover window CW, and the second material M2 may include the other of the substrate 100 and the cover window CW. As an example, the first material M1 may include the substrate 100, and the second material M2 may include the cover window CW. Alternatively, the first material M1 may include the cover window CW, and the second material M2 may include the substrate 100. However, this is an example, and the first material M1 and the second material M2 are not limited thereto.

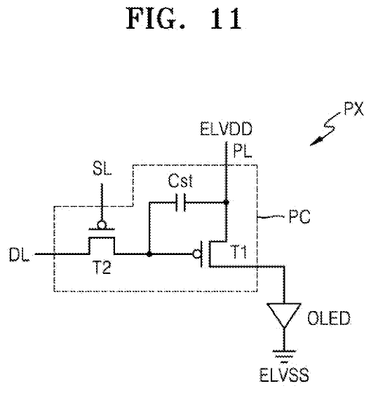

FIG. 11 is an equivalent circuit diagram of one of pixels in a display panel according to some embodiments.

Each pixel PX may include a pixel circuit PC and a display element connected to the pixel circuit PC, wherein the display element may be, for example, an organic light-emitting diode OLED. The pixel circuit PC may include a first thin-film transistor T1, a second thin-film transistor T2, and a storage capacitor Cst. Each pixel PX may be configured to emit, for example, red, green, blue, or white light from the organic light-emitting diode OLED.

The second thin-film transistor T2 is a switching thin-film transistor, may be connected to a scan line SL and a data line DL, and configured to transfer a data voltage to the first thin-film transistor T1 based on a switching voltage, the data voltage being input from the data line DL, and the switching voltage being input from the scan line SL. The storage capacitor Cst may be connected to the second thin-film transistor T2 and a driving voltage line PL and configured to store a voltage corresponding to a difference between a voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and configured to control a driving current according to the voltage stored in the storage capacitor Cst, the driving current flowing from the driving voltage line PL to the organic light-emitting diode OLED. The organic light-emitting diode OLED may emit light having a preset brightness corresponding to the driving current. An opposite electrode (e.g., a cathode) of the organic light-emitting diode OLED may receive a second power voltage ELVSS.

Though it is described with reference to FIG. 11 that the pixel circuit PC includes two thin-film transistors and one storage capacitor, the embodiments according to the present disclosure are not limited thereto. The number of thin-film transistors and the number of storage capacitors may be variously changed according to the design of the pixel circuit PC. As an example, the pixel circuit PC may further include four or more thin-film transistors as well as the two thin-film transistors.

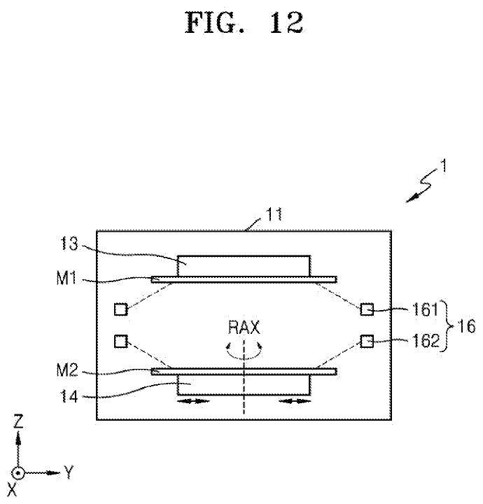

FIG. 12 is a schematic cross-sectional view of the apparatus 1 for manufacturing a display apparatus according to some embodiments.

Referring to FIG. 12, the apparatus 1 for manufacturing the display apparatus may include the first chamber 11, the first stage 13, the second stage 14, the camera unit 16, the controller, and the communication unit. Descriptions that are the same as or similar to those described with reference to FIGS. 1 to 11 are omitted, for convenience of description.

The first chamber 11 may provide an inner space.

The first stage 13 may be located inside the first chamber 11 and may support a first material M1. The first stage 13 may be fixedly arranged with respect to the first chamber 11.

The second stage 14 may be located inside the first chamber 11 and may support a second material M2. The second stage 14 may be movable with respect to the first chamber 11. The second stage 14 may be configured to align the second material M2 such that the second material M2 supported by the second stage 14 is bonded to the first material M1 supported by the first stage 13 at an exact position. As an example, the second stage 14 may perform a linear motion with respect to the first stage 13 and perform a rotational motion around a rotational axis RAX.

The camera unit 16 may be configured to sense image information of the first material M1 and the second material M2. The camera unit 16 may include the first camera 161, the second camera 162. The first camera 161 and the second camera 162 may be located inside the first chamber 11. The first camera 161 may be configured to sense image information of the first material M1, and the second camera 162 may be configured to sense image information of the second material M2.

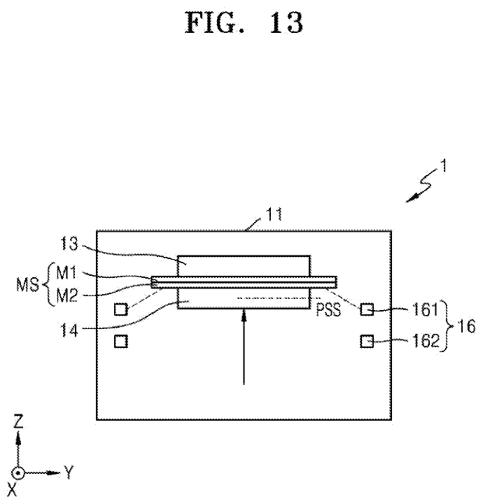

FIG. 13 is a schematic cross-sectional view of the apparatus 1 for manufacturing a display apparatus according to some embodiments.

Referring to FIG. 13, after the process described with reference to FIG. 12, the second stage 14 may move to a final bonding position PSS such that the first material M1 and the second material M2 are bonded as a bonded material MS. As the second stage 14 moves to the final bonding position PSS, the first material M1 and the second material M2 may contact each other and be bonded as the bonded material MS.

When the first material M1 is bonded to the second material M2, at least one of the first camera 161 or the second camera 162 may be configured to sense image information of the bonded material MS. Though it is shown in FIG. 13 that the first camera 161 is configured to sense image information of the bonded material MS, this is only an example, and the second camera 162 may be configured to sense image information of the bonded material MS.

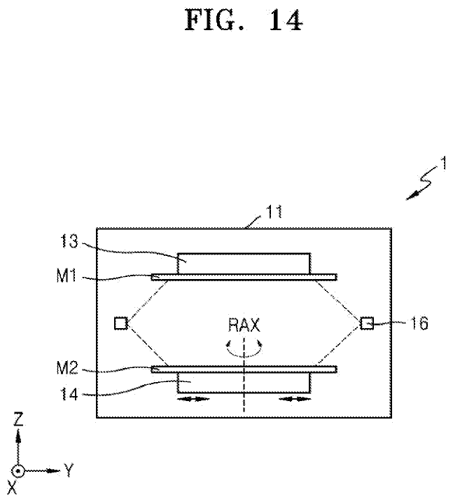

FIG. 14 is a schematic cross-sectional view of the apparatus 1 for manufacturing a display apparatus according to some embodiments.

Referring to FIG. 14, the apparatus 1 for manufacturing the display apparatus may include the first chamber 11, the first stage 13, the second stage 14, the camera unit 16, the controller, and the communication unit. Descriptions that are the same as or similar to those described with reference to FIGS. 1 to 11 are omitted, for convenience of description.

The first chamber 11 may provide an inner space.

The first stage 13 may be located inside the first chamber 11 and may support a first material M1. The first stage 13 may be fixedly arranged with respect to the first chamber 11.

The second stage 14 may be located inside the first chamber 11 and may support a second material M2. The second stage 14 may be movable with respect to the first chamber 11. The second stage 14 may be configured to align the second material M2 such that the second material M2 supported by the second stage 14 is bonded to the first material M1 supported by the first stage 13 at an exact position. As an example, the second stage 14 may perform a linear motion with respect to the first stage 13 and perform a rotational motion around the rotational axis RAX.

The camera unit 16 may be configured to sense image information of the first material M1 and the second material M2. The camera unit 16 may be located inside the first chamber 11. One camera may be configured to sense both image information of the first material M1 and image information of the second material M2.

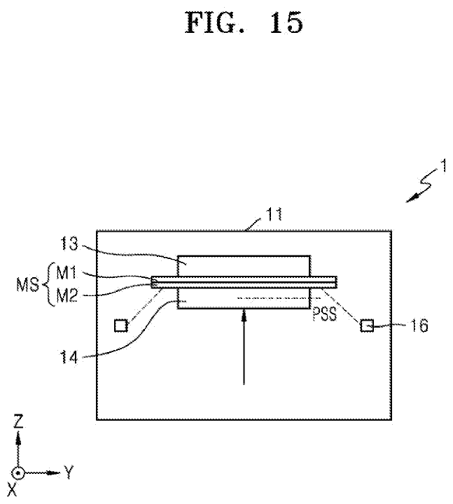

FIG. 15 is a schematic cross-sectional view of the apparatus 1 for manufacturing a display apparatus according to some embodiments.

Referring to FIG. 15, after the process described with reference to FIG. 14, the second stage 14 may move to a final bonding position PSS such that the first material M1 and the second material M2 are bonded as a bonded material MS. As the second stage 14 moves to the final bonding position PSS, the first material M1 and the second material M2 may contact each other and be bonded as the bonded material MS.

When the first material M1 is bonded to the second material M2, the camera unit 16 may be configured to sense image information of the bonded material MS. That is, one camera may be configured to sense image information of the bonded material MS.

According to some embodiments, two materials may be bonded to each other with a minimum or reduced error.

According to some embodiments, as the bonding process of bonding two materials to each other repeats, an alignment error between the two materials may be reduced.

Effects of the disclosure are not limited to the above-mentioned effects and other effects not mentioned may be clearly understood by those of ordinary skill in the art from the following claims, and their equivalents.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. An apparatus for manufacturing a display apparatus, comprising:
a first stage configured to support a first material;
a second stage configured to support a second material and to move to a final bonding position to bond the first material and the second material into a bonded material;
a camera unit configured to sense image information of the first material, the second material, and the bonded material; and
a controller configured to control the second stage,
wherein the controller includes:
an image processor configured to calculate position information of the first material and the second material and alignment information of the bonded material based on the image information sensed by the camera unit;
an operator configured to calculate the final bonding position based on the position information of the first material and the second material calculated by the image processor;
a controller unit configured to move the second stage to the final bonding position calculated by the operator; and
a deep learning unit configured to update the operator through deep learning based on the alignment information of the bonded material calculated by the image processor.

2. The apparatus of claim 1, wherein the operator includes:
an initial bonding position calculator configured to calculate an initial bonding position based on the position information of the first material and the second material calculated by the image processor; and
a bonding position corrector configured to correct the initial bonding position to the final bonding position according to a first correction model.

3. The apparatus of claim 2, wherein the deep learning unit includes:
an error calculator configured to calculate an alignment error of the bonded material based on the alignment information of the bonded material calculated by the image processor;
a correction model corrector configured to correct the first correction model to a second correction model based on the alignment error calculated by the error calculator; and
a correction model updater configured to update the bonding position corrector to correct the initial bonding position to the final bonding position according to the second correction model.

4. The apparatus of claim 3, wherein the second correction model is based on calibration information between the first stage and the second stage, and the camera unit, the position information of the first material and the second material calculated by the image processor, the initial bonding position calculated by the initial bonding position calculator, and the first correction model.

5. The apparatus of claim 3, wherein the bonding position corrector is configured to correct the initial bonding position to the final bonding position according to the second correction model,
the correction model corrector is configured to correct the second correction model to a third correction model based on the alignment error calculated by the error calculator, and
the correction model updater is configured to update the bonding position corrector to correct the initial bonding position to the final bonding position according to the third correction model.

6. The apparatus of claim 5, wherein the correction model corrector is configured to correct the second correction model to the third correction model by taking into account calibration information between the first stage and the second stage, and the camera unit, the position information of the first material and the second material calculated by the image processor, the initial bonding position calculated by the initial bonding position calculator, the first correction model, and the second correction model.

7. The apparatus of claim 1, further comprising a first chamber in which the first stage and the second stage are located,
wherein the camera unit includes:
a first camera inside the first chamber and configured to sense image information of the first material; and
a second camera inside the first chamber and configured to sense image information of the second material.

8. The apparatus of claim 7, wherein at least one of the first camera or the second camera is configured to sense image information of the bonded material.

9. The apparatus of claim 7, further comprising:
a third stage supporting the bonded material;
a second chamber in which the third stage is located; and
a carrier robot configured to carry the bonded material inside the first chamber to an inside of the second chamber,
wherein the camera unit further includes a third camera inside the second chamber and configured to sense image information of the bonded material carried to the inside of the second chamber.

10. The apparatus of claim 1, wherein the first material includes one of a substrate and a cover window, and the second material includes the other of the substrate and the cover window.

11. A method of manufacturing a display apparatus, the method comprising:
arranging a first material on a first stage;
arranging a second material on a second stage;
sensing, by a camera unit, image information of the first material and the second material;
calculating position information of the first material and the second material based on the image information of the first material and the second material;
calculating, by an operator, a final bonding position of the second stage such that the first material and the second material are bonded into a bonded material based on the position information of the first material and the second material;
moving the second stage to the final bonding position;
sensing, by the camera unit, image information of the bonded material;
calculating alignment information of the bonded material based on the image information of the bonded material; and
updating the operator through deep learning based on the alignment information of the bonded material.

12. The method of claim 11, further comprising:
calculating an initial bonding position based on the position information of the first material and the second material; and
correcting the initial bonding position to the final bonding position according to a first correction model.

13. The method of claim 12, further comprising:
calculating an alignment error of the bonded material based on the alignment information of the bonded material;
correcting the first correction model to a second correction model based on the alignment error of the bonded material; and
correcting the initial bonding position to the final bonding position according to the second correction model.

14. The method of claim 13, wherein the second correction model is based on calibration information between the first stage and the second stage, and the camera unit, the position information of the first material and the second material, the initial bonding position, and the first correction model.

15. The method of claim 13, further comprising:
correcting the initial bonding position to the final bonding position according to the second correction model;
correcting the second correction model to a third correction model based on the alignment error of the bonded material; and
correcting the initial bonding position to the final bonding position according to the third correction model.

16. The method of claim 15, further comprising correcting the second correction model to the third correction model by taking into account calibration information between the first stage and the second stage, and the camera unit, the position information of the first material and the second material, the initial bonding position, the first correction model, and the second correction model.

17. The method of claim 11, further comprising:
arranging the first stage and the second stage inside a first chamber;
arranging a first camera inside the first chamber, wherein the first camera is configured to sense image information of the first material; and
arranging a second camera inside the first chamber, wherein the second camera is configured to sense image information of the second material.

18. The method of claim 17, further comprising sensing image information of the bonded material by at least one of the first camera or the second camera.

19. The method of claim 17, further comprising:
arranging a third stage inside a second chamber;
arranging a third camera inside the second chamber;
carrying the bonded material from the inside of the first chamber into the second chamber such that the bonded material is on the third stage; and
sensing, by the third camera, image information of the bonded material.

20. The method of claim 11, wherein the first material includes one of a substrate and a cover window, and the second material includes the other of the substrate and the cover window.
